(19) United States
(12) Patent Application Publication
(10) Pub. No.: US 2003/0117156 A1
(43) Pub. Date: Jun. 26, 2003

(54) Method of construction for high density, adaptable burn-in tool

(76) Inventors: Yee Loy Lam, Singapore (SG); Foo Chai Kueh, Singapore (SG); Kian Hin Teo, Singapore (SG)

Correspondence Address: BUCKLEY, MASCHOFF, TALWALKAR, & ALLISON, 5 ELM STREET, NEW CANAAN, CT, 06840, US

(21) Appl. No.: 10/304,874

(22) Filed: Nov. 26, 2002

(30) Foreign Application Priority Data
Nov. 29, 2001 (GB) 0128618.6

(51) Int. Cl. G01R 31/302

(52) U.S. Cl. 324/752

(57) ABSTRACT

In the present invention there is provided a burn-in system for burning in one or more optoelectronic devices comprising at least one burn-in printed circuit board (PCB). The, or each, burn-in PCB comprises a plurality of mounts for holding the, or each, optoelectronic device, a full population of traces for separate electrical connection to each electrical contact on the or each optoelectronic device, and a PCB connector having a plurality of contacts for external electrical connection to each trace on the burn-in PCB. The burn-in system also comprises a custom PCB. The custom PCB comprises a plurality of input connectors for connecting a plurality of electrical biasing sources to said custom PCB, a plurality of output connectors, each output connector adapted for mating with the PCB connector on a burn-in PCB, thereby providing for electrical connection between the custom PCB and the or each burn-in PCB, and a plurality of electrical routines for electrical connection between the input and output connectors, said routings being arranged so that, in use, the custom PCB connects at least one electrical biasing source to at least one electrical contact on the or each optoelectronic device.

The present invention enhances the burn-in facility by providing flexability of electrical connection from various sources to burn-in mounts.

### FIELD OF THE INVENTION

The present invention relates to the field of burn-in testing of semiconductor devices and particularly to sum-in testing of photonic devices.

### BACKGROUND TO THE INVENTION

Burn-in is a fundamental requirement in semiconductor optoelectronic manufacturing in order to ensure devices with infant mortality type of early failure are screened out and not shipped to customers. Unlike plastic integrated circuit (IC) packages, photonic devices do not have well-established burn-in tools in the industry

Typical burn-in systems for photonic devices are drawer-based with laser mounts or fully assembled butterfly casing mounts to house units for biasing, as shown in FIG. 1. Those mounts 11 have user configurable pin headers on an underside and must be wired properly according to the pin configuration of each product. Electrical connection to current sources and temperature or thermo-electric cooler (TEC) controllers is achieved through printed circuit board (PCB) traces routed to commonly available, low pin count serial connectors linking one current source and one TEC controller to each mount. FIG. 1 shows a vertical PCB 12 for connecting TEC and current sources with PCB connector 13. TEC controller connectors 14 and current source connectors 15 are also shown.

This classical apparatus does not have the flexibility to connect multiple current sources and multiple controllers of various sorts to one mount, which is an increasing requirement for burn-in of more advanced products, such as a tuneable laser. Methods nave been sought in the industry to overcome this limitation. However, the solutions are normally tailored with another new burn-in system for a new product, and PCBs with expensive mounts soldered onto them are not sharable among different systems due to electrical connection to current sources and TEC controllers being made through “hard-wired” PCB traces.

Another problem exists when burn-in products require a common resource, such as a pattern generator or a data acquisition unit, to be shared by many mounts. Due to space constraints, it is troublesome and untidy to wire up jumpers on the user configurable pin headers to make all the necessary branches share the common resource.

### SUMMARY OF THE INVENTION

According to the present invention, a burn-in system for burning in one or more optoelectronic devices comprises;

at least one burn-in printed circuit board (PCB), the or each burn-in PCB comprising:

a plurality of mounts for holding the or each optoelectronic device;

a full population of traces for separate electrical connection to each electrical contact on the or each optoelectronic device; and,

a PCB connector having a plurality of contacts for external electrical connection to each trace on the burn-in PCB; and,

a custom PCB comprising

a plurality of input connectors for connecting a plurality of electrical biasing sources to said custom PCB,

a plurality of output connectors, each output connector adapted for mating with the PCB connector on a burn-in PCB, thereby providing for electrical connection between the custom PCB and the or each burn-in PCB; and,

a plurality of electrical routings for electrical connection between the input and output connectors, said routings being arranged so that, in use, the custom PCB connects at least one electrical biasing source to at least one electrical contact on the or each optoelectronic device.

Preferably, the system further comprises at least one ribbon cable for connecting an output connector on the custom PCB to the PCB connector on a burn-in PCB.

Preferably, a connector is a nigh pin count connector. Preferably, the or each PCB is drawer mounted.

Preferably, the custom PCB is designed for burning in a predetermined type of optoelectronic device. Preferably, the optoelectronic device comprises a laser diode.

Preferably, the system further comprises an electrical biasing source connected to an input connector of the custom PCB. The electrical biasing source is selected from one of the following current source, thermo-electric cooler controller, pattern generator and data acquisition unit.

### BRIEF DESCRIPTION OF DRAWINGS

Examples of the present invention will now be described in detail with reference to the accompanying drawings, in which.

FIG. 1 shows a typical burn-in system in accordance with the prior art;

FIG. 2 shows a burn-in system in accordance with the present invention; and,

FIG. 3 shows possible configurations of a burn-in system in accordance with the present invention.

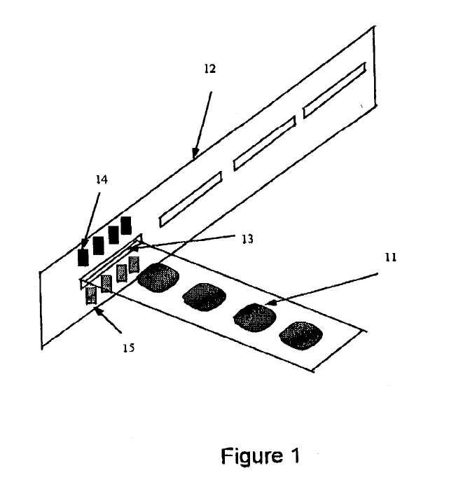

### DETAILED DESCRIPTION

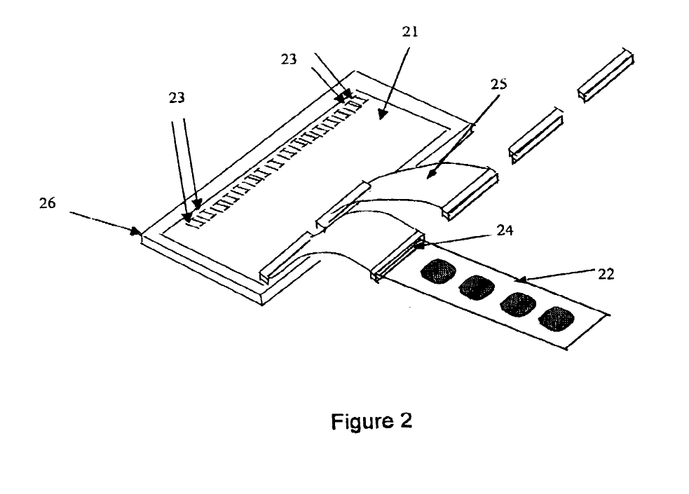

According to one example of the present invention a distributed printed circuit board (PCB) 21 is used to interface the fixed mounting requirements of the laser to the power and control lines needed for running different devices, as shown in FIG. 2 This transfers all the mount configurations to the PCB 21 thus providing a lot of flexibility in interconnecting the necessary power and control lines to the mounts. Manually configurable pin headers are not necessary, and the internal PCBs 22 with mounts soldered onto them are fully populated with traces making each pin accessible through high pin count connectors. The external PCB 21 can be custom made with the necessary routing for each product. Its input ends 23 are connectors from various biasing sources, such as current sources, TEC controllers, pattern generators and data aquisition units, and its output ends 24 are high pin count connectors, providing electrical connection to drawer mounted PCB 22 through ribbon cables 25. A fixture 26 may also be provided to hold the custom made PCB 21.

The new design allows drawer mounted PCBs with expensive mounts to be usable among different products as long as the mount is compatible. Operators just need to change one external PCB, and no manual re-wiring on pin headers is required when changing to another product for burn-in. In manual re-wiring, a lot of un-tightening and tightening of screws has to be performed and operators need to be particularly careful when wiring jumpers to pin-headers in accordance with device configuration.

The present invention enhances the burn-in facility by providing flexibility of electrical connection from various sources to burn-in mounts. Burn-in needs for future products are also taken care of. As well as increasing demand for more current sources and TEC controllers to bias-up one mount, there are needs to share common resources as well as plug-in new resources for burn-in.

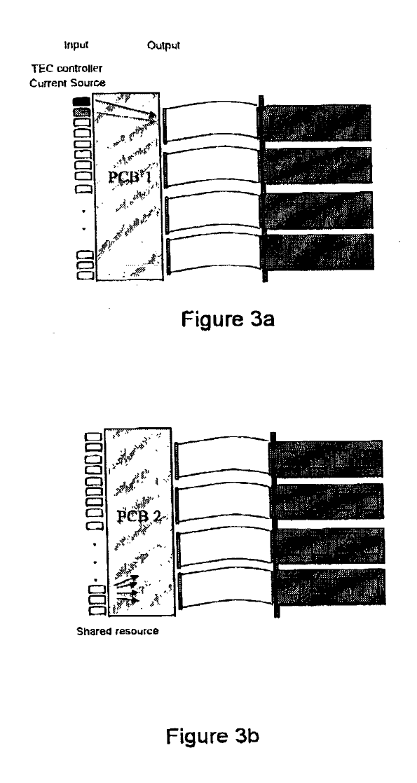

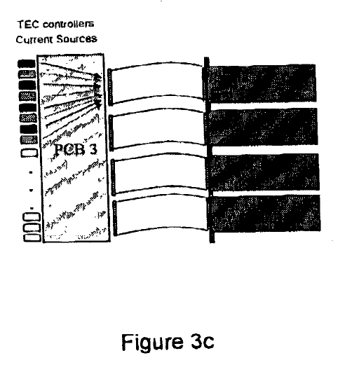

FIG. 3 snows some of the possible configurations that can be easily realised with the present invention. FIG. 3a snows a configuration for products that require one TEC controller and one current source during burn-in. FIG. 3b snows a configuration for products that require common resources such as a pattern generator and a data acquisition unit for all devices under test (DUTS). FIG. 3c shows a configuration for products that require multiple TEC controllers and current sources for burn-in.

1. A burn-in system for burning in one or more optoelectronic devices comprising;
at least one burn-in printed circuit board (PCB), the or each burn-in PCB comprising:
a plurality of mounts for holding the or each optoelectronic device;
a full population of traces for separate electrical connection to each electrical contact an the or each optoelectronic device; and,
a PCB connector having a plurality of contacts for external electrical connection to each trace on the burn-in PCB; and,
a custom PCB comprising:
a plurality of input connectors for connecting a plurality of electrical biasing sources to said custom PCB,
a plurality of output connectors, each output connector adapted for mating with the PCB connector on a burn-in PCB, thereby providing for electrical connection between the custom PCB and the or each burn-in PCB; and,
a plurality of electrical routings for electrical connection between the input and output connectors, said routings being arranged so that, in use, the custom PCB connects at least one electrical biasing source to at least one electrical contact on the or each optoelectronic device.

2. A system according to claim 1, further comprising at least one ribbon cable for connecting an output connector on the custom PCB to the PCB connector on a burn-in PCB.

3. A system according to claim 1 or 2, in which a connector is a high pin count connector.

4. A system according to any preceding claim, in which the or each burn-in PCB is drawer mounted.

5. A system according to any preceding claim, in which the custom PCB is designed for burning in a predetermined type of optoelectronic device.

6. A system according to claim 5, in which the optoelectronic device comprises a laser diode.

7. A system according to any preceding claim, further comprising an electrical biasing source connected to an input connector of the custom PCB.

8. A system according to claim 7, in which the electrical biasing source is selected from one of the following current source, thermo-electric cooler controller, pattern generator and data acquisition unit.
